(19) United States
(12) Patent Application Publication
(10) Pub. No.: US 2009/0083977 A1
(43) Pub. Date: Apr. 2, 2009

(54) Method for Filling Via Holes in Semiconductor Substrates

(76) Inventors: Andre Hanke, Strausberg (DE); Helmuth Hermann, Dresden (DE); Michael Dunkel, Dresden (DE)

Correspondence Address: SLATER & MATSIL, L.L.P., 17950 PRESTON ROAD, SUITE 1000, DALLAS, TX, 75252, US

(21) Appl. No.: 11/864,396

(22) Filed: Sep. 28, 2007

(51) Int. Cl. H05K 3/42

(52) U.S. Cl. 29/852

(57) ABSTRACT

A method for filling either blind or through via holes in a semiconductor substrate involves the use of dielectric or conductive polymer paste, and a drying and a curing process of the polymer paste.

### TECHNICAL FIELD

The present method relates generally to the field of semiconductor fabrication and, more specifically, to filling blind or through vias in semiconductor substrates with a conductive or non-conductive material.

### BACKGROUND

The development of innovative electronic products is influenced by increasing requirements regarding the functionality of the products, further miniaturization and a high reliability with a simultaneously cost-effective production. Therefore, the specifications on the interconnection technology inside of the products tighten continuously.

In the so called Through Silicon Interconnect Technology (TSV—Through Silicon Via), electric connections are led directly through the chip. At this, via holes are formed directly into the semiconductor substrate and filled with conductive or non-conductive material. Further, because of the more and more increasing scale integration, the aspect ratio of the via holes also increases so that filling the via holes becomes more difficult and thus, the required reliability of the connection is not ensured. Currently, the diameter of the via holes is known in the range of 10 μm wherein in the future, technologies for diameters of less than 1 μm will be required.

### BRIEF DESCRIPTION OF THE DRAWINGS

For a more complete understanding of the present invention, and the advantages thereof, reference is now made to the following descriptions taken in conjunction with the accompanying drawing, in which:

FIGS. 1a to 1f illustrate several steps for filling via holes in a semiconductor substrate by stencil printing;

FIGS. 2a to 2f illustrate several steps for filling blind via holes in a semiconductor substrate;

FIGS. 3a to 3c illustrate several steps for filling via holes in a semiconductor substrate by stencil printing combined with a magnetic field; and

FIG. 4 illustrates schematically an embodiment of the treatment process of the semiconductor substrate.

### DETAILED DESCRIPTION OF ILLUSTRATIVE EMBODIMENTS

A method of cost-effective filling of high aspect ratio via holes capable of multiple integration of active and passive components by through silicon interconnections is proposed. Wafers proposed as the packaging material and conventional IC manufacturing processes are used to fabricate the components including x- and y-directional interconnections. For a stacked structure comprising a chip to chip stack or a wafer to wafer stack needs the formation of vias for z-directions interconnections.

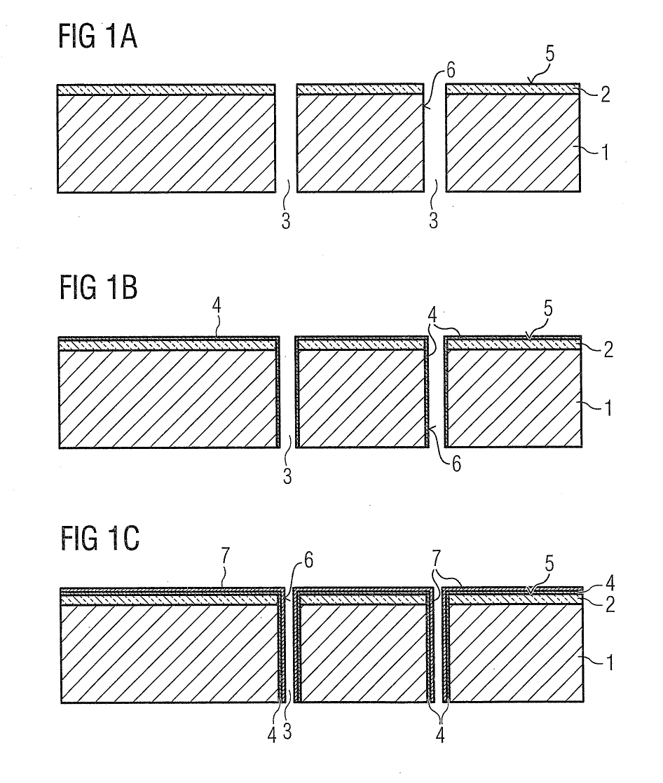

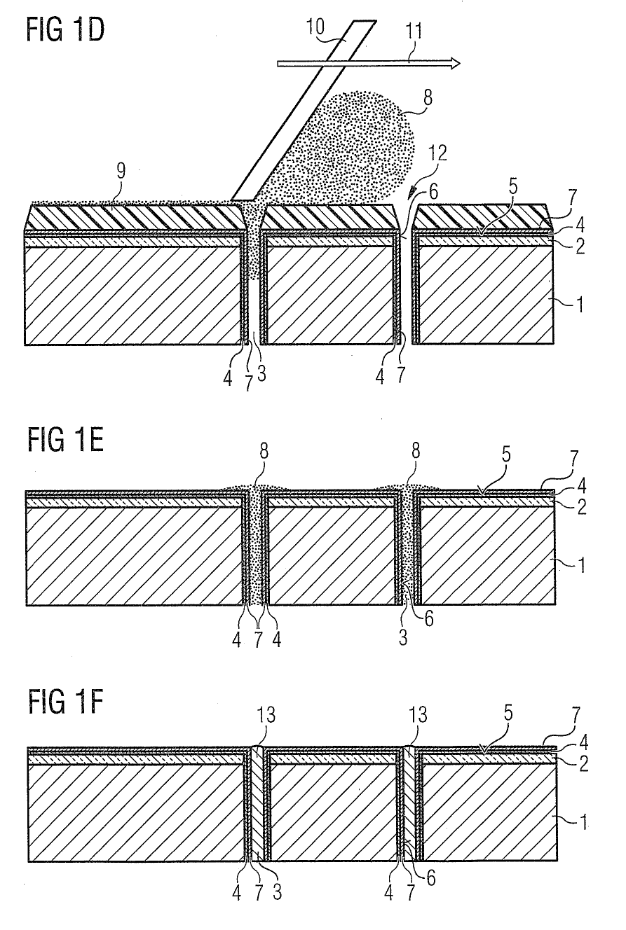

FIG. 1a illustrates a semiconductor substrate 1 with an active area 2, in which an integrated circuit is formed. The semiconductor substrate exemplary has two via holes 3 at high aspect ratio formed as through via holes and extending through the entire semiconductor substrate 1. The below mentioned method is also applicable to fill blind via holes ending inside the semiconductor substrate 1.

On the upper surface 5 of the semiconductor substrate 1 including the surface inside the via holes 3, a dielectric layer 4 is deposited (FIG. 1b) by means of, e.g., a conventional process such as spin coating. The dielectric layer 4 serves to electrically isolate the semiconductor substrate 1 from a electrical conductive material filling the via holes 3. In one embodiment this dielectric layer is formed of polyimide which conventionally is a cost-effective material for passivation of semiconductor material. It is understood that other dielectric materials are applicable for this purpose. It is also understood that the dielectric layer 4 at least inside the via holes 3 does not need to be applied if the via holes will not be filled with any of the conductive material.

In an embodiment, the dielectric layer 4 on the upper surface 5 and inside the via holes 3 is covered by an interface layer 7 (FIG. 1c). The interface layer 7 eventually forms the inner surfaces 6 of the via holes 3. The interface layer 7 comprises a hydrophilic material having the ability of being easily wettable and that increases the adherence effect of the polymer paste filled in the via holes 3. Therefore, according to the above characteristic, the interface layer 7 enables the via holes 3 to be filled void-free with polymer paste. For instance, a layer of Al₂O₃ would be suitable as an interface layer 7, which can be deposited by a reactive sputtering process. Alternatively, instead of Al₂O₃, another hydrophilic material can be used as interface layer 7. Furthermore, it is well known that a ceramic layer as well has the hydrophilic characteristic. The interface layer 7 can be deposited both on the dielectric layer 4 or directly on the inner surface 6 of the via.

FIG. 1d illustrates the supplying of polymer paste to the surface of the semiconductor substrate 1 by stencil printing. In a stencil printing process the supplying takes place in a structured way due to a stencil 9 arranged on the upper surface 5.

According to the requirements at the filling of the via holes 3, a polymer dielectric or a polymer conductor paste is used as the polymer paste 8. The material of the proposed polymer paste 8 and its viscosity is adapted, e.g., to the environment or to the performance of the semiconductor substrate 1 and to its geometric features. In an embodiment, the polymer conductor paste is formed by a polymer matrix including a conductor powder (not shown) in a range of about 70 to 90 weight percent whereas a maximum dimension of the powder particles is less than about 300 nm. Preferably, the paste includes conductor powder about 80 weight percent. The conductor powder includes metal powder having a high conductivity, preferably silver powder. Such polymer paste 8 including nanoparticles of silver is suitable for the filling of the via holes 3 having a high aspect ratio through stencil printing. Those warrant also, after the curing of the polymer matrix, a good conductivity of the formed interconnections because processes of oxidation of the conductor powder are prevented.

Moreover, this polymer paste 8 allows a printing process with a high-quality printing. The described polymer paste 8 shows a good ability to release out of the stencil. Also, in several successive printing procedures applied to several semiconductor substrates 1, no decrease of quality has been observed.

A certain amount of polymer paste 8 is applied on the top of the stencil 9 over a section of the semiconductor substrate 1 having no via holes 3, and is distributed eventually by means of a squeegee 10 in application direction into the openings 12 of the stencil 9 wherein each of the openings are arranged above the via holes 3 and at least into the upper part of the via holes 3 (FIG. 1d). At the subsequent removal of the stencil 9 from the semiconductor substrate 1, the polymer paste 8 releases out of the openings 12 and fills the via holes 3 completely and void-free because of its viscous characteristic and the good wetting characteristic of the interface layer 7 (FIG. 1e). If remains of the polymer paste 8 are left on the surface of the semiconductor substrate 1 around the via holes 3 an appropriate process will be used, e.g., a clean plasma process, to remove them subsequently.

Filling of the via holes 3 with a polymer paste 8 requires a drying and curing process which can carried out by heating the semiconductor substrate 1 at a comparatively low temperature. For instance, temperatures in the range of about 120° C. to 220° C. for curing of the polymer matrix are sufficient. Furthermore, this process can be complemented by a prior clearing process at room temperature.

At the clearing process, the polymer paste 8 rests for a while so that possible irregularities coming from the supplying of the polymer paste 8 can be cleared and a part of the solvent can be evaporated. Further, the clearing process is optional and can be left out, e.g., if the supplying of the polymer paste 8 takes place without any clearing required. For instance, the above described silver polymer paste 8 is dried and cured in about 30 minutes at a temperature of about 200° C. without a prior clearing process. Other polymer pastes rest 5 to 10 minutes. After the closing drying and curing process, the via holes 3 are filled with solid interconnection 13 (FIG. 1f).

In another embodiment, the stencil remains on the upper surface 5 of the semiconductor substrate 1 when the curing process is carried out. In this embodiment the openings 12 of the stencil serves as a depot of filling material. For this purpose, the volume of the opening 12 is adapted to the volume of the via holes 3 and to the shrinking or expansion of the polymer paste 8 in the drying and curing process. In FIG. 1d, the openings are funnel shaped. In other embodiments, the openings 12 can have other shapes as well which can be produced in the stencil. Moreover, it is not required that the openings 12 are arranged directly above the via holes 3. During the application and drying and curing process, the polymer paste 8 can be led to the single via holes 3 by means of channels (not shown) which are formed in the stencil 9.

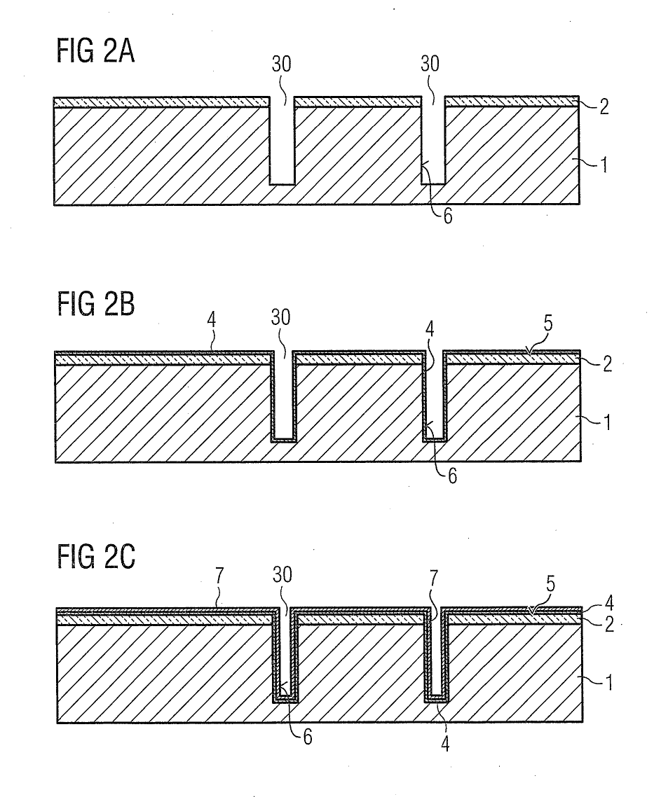

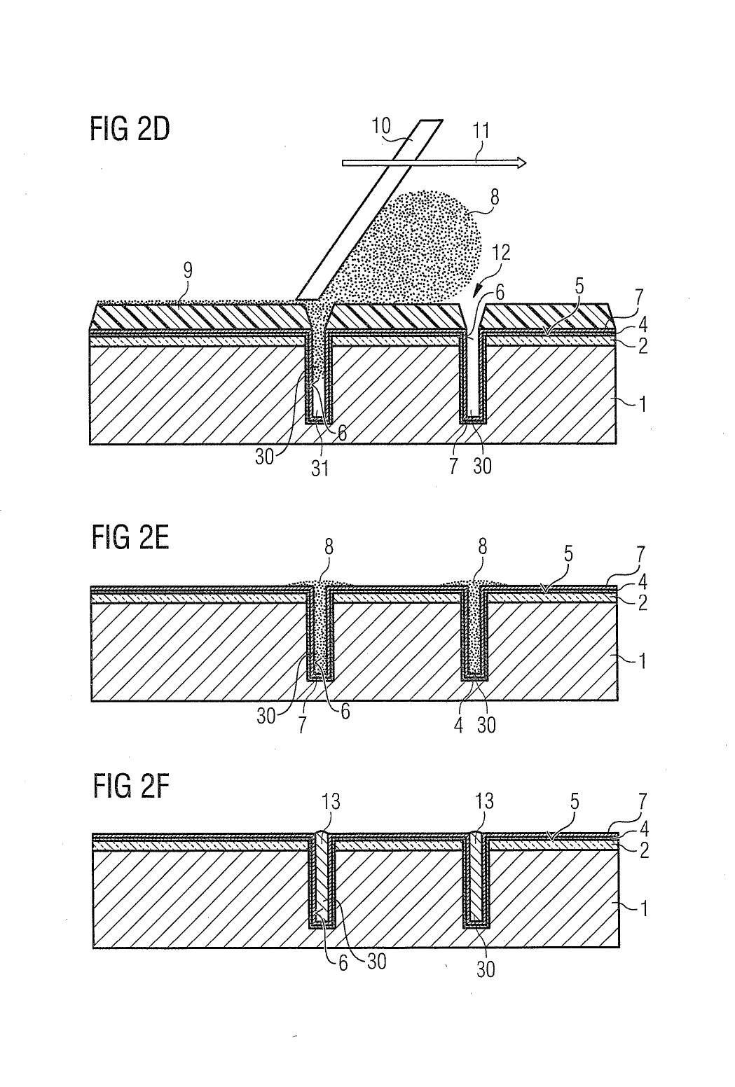

In another embodiment illustrated in FIG. 2a to 2f, filling of via holes 3 is supported by a vacuum process wherein for the filling process there is a pressure difference between the pressure in via holes 3 and the pressure above the polymer paste applied on the upper end of the via holes 3.

In this vacuum process the printing device and the semiconductor substrate 1 arranged on a stage of the printing device (not shown) are depressurized down to a prescribed pressure. Next, the polymer paste 8 is squeezed in the openings 12 of the stencil 9 and on the via holes 3 at the upper surface of the semiconductor substrate 1 (FIG. 2d). In one embodiment the polymer paste 8 is squeezed in the upper end part of the via holes 3. Then, the pressure inside the printing device is increased, e.g., to the atmospheric pressure. At this moment, the cavities 31 formed in the via holes 3 below the polymer paste 8 have a lower pressure than the surroundings, and the polymer paste 8 is buried in the via holes 3 (FIG. 2e).

In FIG. 2a to 2e blind via holes 30 (FIG. 2a) are filled by a vacuum process. Alternatively, through via holes can be filled by a vacuum process when the semiconductor substrate 1 is sealingly mounted on a stage of the printing device or when the bottom end parts of the via holes 3 are sealingly closed in a different way. The semiconductor substrate 1 in the embodiment of FIG. 2a to 2e comprises a dielectric layer 4 (FIG. 2b) and an interface layer 7 (FIG. 2c) described in FIG. 1a to 1c. According to the latter two layer's embodiment and characterization, it can be referred to the above description of these figures. Also, the above described possibilities of variations of the inner surface 6 of the via holes 3 are applicable at the vacuum process. Further, the vacuum process does not have an influence on the use, the application and the drying and curing process of the polymer paste 8 so that it can be referred as well in this respect to the above descriptions.

In another embodiment, the burying process of the polymer paste 8 is supported by a magnetic field which affects the polymer paste 8. For this purpose, the polymer paste 8 includes particles of a magnetic material (not shown). Suitable magnetic materials are, e.g., ferromagnetic metals such as iron, cobalt or nickel, or ferromagnetic material such as magnetite other chemical compounds of those materials. The size and the weight percent of the magnetic particles depend on different factors, e.g., the strength of the magnetic field, the aspect ratio of the via holes 3, the viscosity of the polymer paste 8, the wettability of the material of the inner surface 6 of the via holes 3 and others.

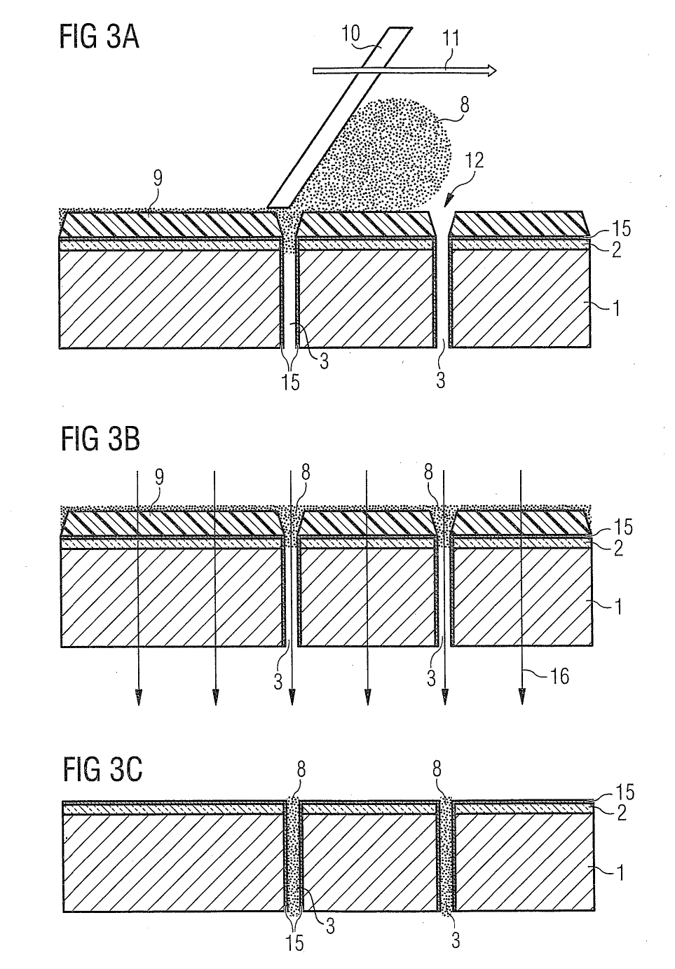

Supplying of a certain volume of the polymer paste 8 including magnetic particles to the semiconductor substrate 1 is carried out on the embodiment by stencil printing. The semiconductor substrate 1 in an embodiment illustrated in FIG. 3a to 3d has a passivating layer 15. Also, at the filling process wherein a magnetic field affects the polymer paste 8, the above mentioned variations of layers on the semiconductor substrate 1 and inside the via holes 3 are possible.

The polymer paste 8 is applied on the top of the stencil 9 over a part of the semiconductor substrate 1 having via holes 3, and is distributed eventually by means of a squeegee 10 in application direction into the openings 12 of the stencil 9 wherein each of the openings are arranged above the via holes 3 (FIG. 3a). It is understood that the volumes of the openings 12 are adjusted to the volumes of the via holes 3.

Then, by means of a suitable magnetic device (not shown), a magnetic field is induced, illustrated in FIG. 3b by the magnetic lines of force 16. The magnetic field is orientated in a way, that the force affecting the magnetic particles draws those and thus, the polymer paste 8 into the via holes 3. When the via holes 3 are completely filled (FIG. 3c), the magnetic field is interrupted. Alternatively or complementary, the flowing out of the polymer paste 8 out of the via holes 3 can also be prevented by means of an appropriate temporary seal at the bottom end of the via holes 3.

Through the described process, either through via holes or blind via holes can be filled void-free. Moreover, this process is applicable either for dielectric polymer paste or for conductive polymer paste. At the latter, magnetic particles are added to the conductor particles.

For increasing the viscosity of the polymer paste 8, it is possible to use a magnetic alternating field so that because of the movements of the magnetic particles a warming of the polymer paste 8 takes place. In this way, the force of the magnetic field can be reduced, e.g., to minimize its influence on the integrated circuit of the semiconductor substrate 1.

In another embodiment, a demixing of the magnetic particles out of the polymer paste 8 takes place after filling the via holes 3 to remove the particles and to avoid any later influence of the particles on the integrated circuit.

After filling the via holes 3, any remains left of the polymer paste 8 on the surfaces of the semiconductor substrate 1 can be removed. Subsequently, the polymer paste 8 is dried and cured as already described above in detail. In one embodiment, the drying and curing process is carried out by heat creation inside the magnetic polymer paste 8. An alternating magnetic field induces heat in the polymer paste 8 by oscillative movement of the magnetic particles. Due to heat induction only in the filled via holes 3, there is low heat load of the semiconductor substrate 1.

In another embodiment, the adhesion of the inner surface 6 of the via holes 3 is increased by increasing its surface energy. As it is well known, each system tends to minimize surfaces with a high surface energy. Therefore, materials with a high surface energy are wetted very well by materials with a lower surface energy. This effect is applicable on plastic surfaces by treating them with plasma.

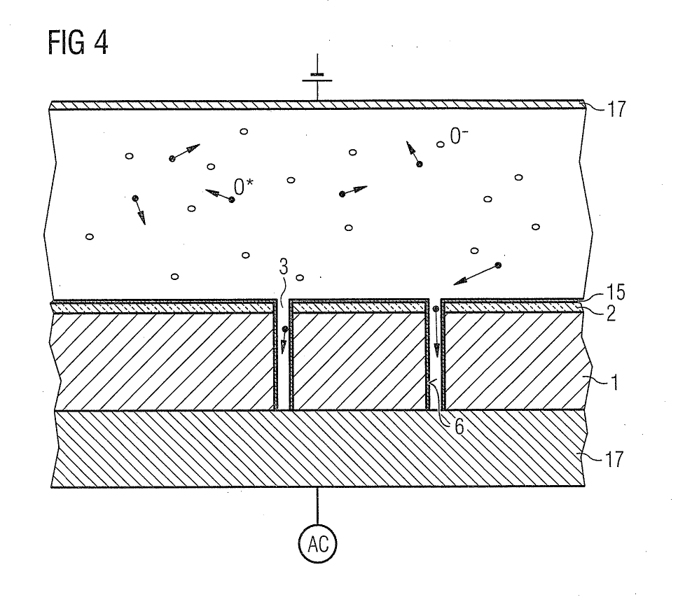

In FIG. 4, a semiconductor substrate 1 is arranged on a plate-like electrode 17 which is opposite to a second electrode. The upper surface 5 of the semiconductor substrate 1 and its surface inside the via holes 3 is covered by a passivating layer 15, e.g., polyimide. In between both electrodes 17, a plasma is produced at a sufficiently high alternating current and an oxygen atmosphere. Suitable plasma processes include corona discharge or low pressure plasma modification of ammonia or oxygen.

Within the plasma, oxygen ions O⁻ and oxygen radicals O* are produced, among others. Both components of the plasma lead to an activation of the inner surface 6 of the hydrophobic passivating layer 15 wherein the oxygen radicals are free to move within the plasma and less affected by the electrostatic charging of the surface of the passivating layers 15 during the plasma process. Through the effect of both of the plasma components on the surface of the polyimide, reactive functional groups are formed, e.g., amino groups, amid groups, hydroxyl groups, carbonyl groups or carboxyl groups, by the oxygen ions and radicals combined with the non-polar plastic surface and forming polar hydrophilic groups. Therefore, the surface energy is increased and the wettability of the surface of the passivation layer 15 is improved. Those modifications of the plastic only take place in the upper monolayers of the plastic. The characteristics of the material are not changed.

The described treatment of the inner surface 6 does not have another influence on the filling process except the improvement of the wetting of a plastic surface. Thus, it is possible to treat, prior to each of the above described processes, the plastic surface inside the via holes 3 and to benefit the filling of the via holes 3 with the polymer paste 8.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. Accordingly, the particular arrangements disclosed are meant to be illustrative only and not limiting as to the scope of the invention, which is to be given the full breadth of the appended claims, and any and all equivalents thereof.

What is claimed is:

1. A method of filling via holes in a semiconductor substrate, the method comprising:
providing a semiconductor substrate having via holes; and
filling the via holes with a polymer paste.

2. The method of claim 1, wherein the polymer paste is electrically conductive.

3. The method of claim 2, wherein the polymer paste includes particles of a conductor material.

4. The method of claim 3, wherein a maximum dimension of the conductor material is less than 300 nm.

5. The method of claim 3, wherein the polymer paste includes an amount of the conductor material in a range of 70-90 weight percent.

6. The method of claim 1, wherein an inner surface of each via hole is treated to increase surface energy of each via hole.

7. The method of claim 6, wherein the inner surface is treated with plasma.

8. The method of claim 7, wherein the inner surface is treated by corona discharge.

9. The method of claim 7, wherein the inner surface is treated by low pressure plasma modification.

10. The method of claim 1, further comprising depositing a hydrophilic layer in each via hole.

11. The method of claim 1, further comprising heating the semiconductor substrate after filling the via holes to dry and cure the polymer paste.

12. A method of filling via holes in a semiconductor substrate, the method comprising:
providing a semiconductor substrate having via holes;
supplying polymer paste partially overlying the upper surface of the semiconductor substrate adjacent the via holes; and
applying a pressure higher to force the polymer paste in the via holes of the semiconductor substrate.

13. The method of claim 12, wherein a certain volume of polymer paste is supplied by stencil printing.

14. The method of claim 13, wherein the polymer paste is supplied in a volume substantially equal to a volume of an opening in the stencil and wherein the stencil remains on the surface of the semiconductor substrate while applying the pressure.

15. The method of claim 12, further comprising treating an inner surface of the via holes to increase a surface energy of the via holes.

16. The method of claim 12, wherein the polymer paste is electrically conductive.

17. The method of claim 12, further comprising heating of the semiconductor substrate after applying the pressure to dry and cure the polymer paste.

18. A method of filling via holes in a semiconductor substrate, the method comprising:
providing a semiconductor substrate having via holes;
supplying a polymer paste including particles of a magnetic material to a surface of the semiconductor substrate adjacent the via holes; and
applying a magnetic field to the polymer paste to bury the polymer paste in the via holes.

19. The method of claim 18, wherein supplying the polymer paste comprises stencil printing to the surface of the semiconductor substrate.

20. The method of claim 19, wherein the polymer paste is supplied in a volume that is substantially equal to a volume of an opening in the stencil and wherein the stencil remains on the surface of the semiconductor substrate during application of the magnetic field.

21. The method of claim 18, wherein the magnetic field comprises an alternating field.

22. The method of claim 18, further comprising treating the inner surface of each via hole prior to supplying the polymer paste, the treating to increase surface energy of the via holes.

23. The method of claim 18, wherein the polymer paste is electrically conductive.

24. The method of claim 18, further comprising heating the semiconductor substrate after applying the magnetic field, the heating causing the polymer paste to be dried and cured.

25. The method of claim 18, wherein the polymer paste is dried and cured by heat created inside the polymer paste by means of an alternating magnetic field.
